(19) United States
(12) Patent Application Publication
(10) Pub. No.: US 2019/0267513 A1
(43) Pub. Date: Aug. 29, 2019

(54) SEMICONDUCTOR DEVICE AND LIGHT-EMITTING DEVICE

(71) Applicant: Toyoda Gosei Co., Ltd., Kiyosu-shi (JP)

(72) Inventors: Ryoki Kamada, Ichihara (JP); Shinichi Matsui, Ichihara (JP); Hideki Omoya, Ichihara (JP); Hisayuki Miki, Ichihara (JP)

(21) Appl. No.: 16/285,441

(22) Filed: Feb. 26, 2019

(30) Foreign Application Priority Data
Feb. 27, 2018 (JP) 2018-033725

(51) Int. Cl. H01L 33/32; H01L 33/00; H01L 33/38; H01L 33/10

(52) U.S. Cl. CPC H01L 33/32; H01L 33/10; H01L 33/38; H01L 33/007

(57) ABSTRACT

To provide a light-emitting diode in which cracking or peeling of interlayer insulating film is suppressed. The first interlayer insulating film is continuously formed in a film on a DBR layer, a first p-electrode, and a first n-electrode. The first interlayer insulating film is a multilayer formed by alternately depositing a SiO₂ layer and a TiO₂ layer, and the number of layers is eleven. The SiO₂ layer is formed of a material having a property of generating compressive stress. When the light-emitting diode according to the first embodiment is exposed to a high temperature, the TiO₂ layer in the first interlayer insulating film changes its property from generating compressive stress to generating tensile stress. The tensile stress by the TiO₂ layer and the compressive stress by the SiO₂ layer counteract each other. As a result, the internal stress of the first interlayer insulating film is relaxed.

### BACKGROUND OF THE INVENTION

### Field of the Invention

The present invention relates to a Group III nitride semiconductor device characterized in the structure of interlayer insulating film, and more specifically to a light-emitting diode. The present invention also relates to a light-emitting device having the light-emitting diode sealed with glass, and a production method therefor.

### Background Art

A light-emitting device having a light-emitting diode sealed with glass is known (Patent Document 1). It has advantages of being excellent in light resistance, heat resistance, gas barrier property, and environment resistance, compared to a light-emitting diode sealed with silicon resin or epoxy resin.

A light-emitting diode having the following structure is well-known. A plurality of contact electrodes are formed in a dot pattern. An interlayer insulating film and a pad electrode are sequentially deposited on the contact electrode. The contact electrode and the pad electrode are connected through the holes formed in the interlayer insulating film.

In the Group III nitride semiconductor ultraviolet light-emitting diode, a current is hardly diffused in the surface due to high Al composition ratio of semiconductor layer. Therefore, the electrode structure as disclosed in Patent Document 2 may be employed in the ultraviolet light-emitting diode.

Patent Document 1: Japanese Patent Application Laid-Open (kokai) No. 2010-27792
Patent Document 2: Japanese Patent Application Laid-Open (kokai) No. 2015-60886

However, it was found that peeling occurs between the interlayer insulating film and the electrode, and cracks occur in the interlayer insulating film when the electrode structure as disclosed in Patent Document 2 is employed in the Group III nitride semiconductor based ultraviolet light-emitting diode, and the light-emitting diode is sealed with glass as in Patent Document 1. It caused problems such as deterioration of electric and optical properties of the light-emitting diode or partial light emission.

### SUMMARY OF THE INVENTION

In view of the foregoing, an object of the present invention is to provide a semiconductor device in which peeling of the interlayer insulating film from the electrode or crack occurrence in the interlayer insulating film is suppressed.

In one aspect of the present invention, there is provided a semiconductor device comprising:

a sapphire substrate;

a Group III nitride semiconductor layer formed on the sapphire substrate;

a first electrode formed on or above the Group III nitride semiconductor layer;

an interlayer insulating film formed on the first electrode; and

a second electrode formed on the interlayer insulating film, the second electrode being connected with the first electrode through holes formed in the interlayer insulating film,

wherein the interlayer insulating film is a multilayer film formed by alternately depositing a first insulating film made of a material generating a tensile stress and a second insulating film made of a material generating a compressive stress in three or more layers.

The ratio of thickness of the first insulating film to the sum of thicknesses of the first insulating film and the second insulating film is preferably 0.1 to 0.5. Within this range, the internal stress applied to the interlayer insulating film can be further relaxed, and breakdown voltage can be further increased. The thickness ratio is more preferably, 0.1 to 0.4, and further preferably, 0.2 to 0.3.

The top layer and the bottom layer of the interlayer insulating film are preferably the second insulating film. This can improve the adhesiveness of the interlayer insulating film with the first electrode and the second electrode.

The first insulating film may be formed of any material as long as it generates a tensile stress, for example, TiO₂. The second insulating film may be formed of any material as long as it generates a compressive stress, for example, SiO₂, SiN, and Al₂O₃. When the second insulating film is formed of SiO₂, the first electrode is preferably a multilayer whose top layer is preferably formed of at least one of Ta and Mo. Difference in thermal expansion coefficient is reduced, thereby suppressing cracks or peeling of the interlayer insulating film when the diode is exposed to a high temperature.

The present invention is applicable to any semiconductor device, and particularly suitable to a light-emitting diode. Also, the present invention is particularly suitable to an ultraviolet light-emitting diode. When the present invention is applied to a light-emitting diode, the interlayer insulating film may have a distributed bragg reflector (DBR) structure.

The present invention is suitable to a light-emitting diode sealed with glass in the light-emitting device. When sealing with glass, the light-emitting diode is exposed to a high temperature. Even in such a case, the present invention can suppress cracks or peeling of the interlayer insulating film. It is particularly suitable when the glass sealing temperature is 400° C. or more.

According to the present invention, the internal stress applied to the interlayer insulating film is relaxed, and peeling or cracks of the interlayer insulating film can be suppressed. Breakdown voltage can also be increased.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the structure of a light-emitting diode according to the first embodiment;

FIG. 2 is a top view of the light-emitting diode according to the first embodiment;

FIG. 3 is a schematic view of the structure of a first interlayer insulating film 18;

FIG. 4 is a graph comparing internal stresses generated in the first interlayer insulating film 18.

FIG. 5 is a graph showing the relationship between film thickness ratio and internal stress;

FIG. 6 is a graph comparing breakdown voltage of the first interlayer insulating film 18;

FIG. 7 is a graph showing the relationship between film thickness ratio and breakdown voltage;

FIGS. 8A to 8D are graphs showing insulation resistance of the insulating film after heating;

FIGS. 9A and 9B are photos of the top view of the light-emitting diode after heating; and

FIG. 10 is a schematic view of the structure of a light-emitting device according to the second embodiment.

### DETAILED DESCRIPTION OF PREFERRED EMBODIMENTS

Specific embodiments of the present invention will next be described with reference to the drawings. However, the present invention is not limited to these embodiments.

### First Embodiment

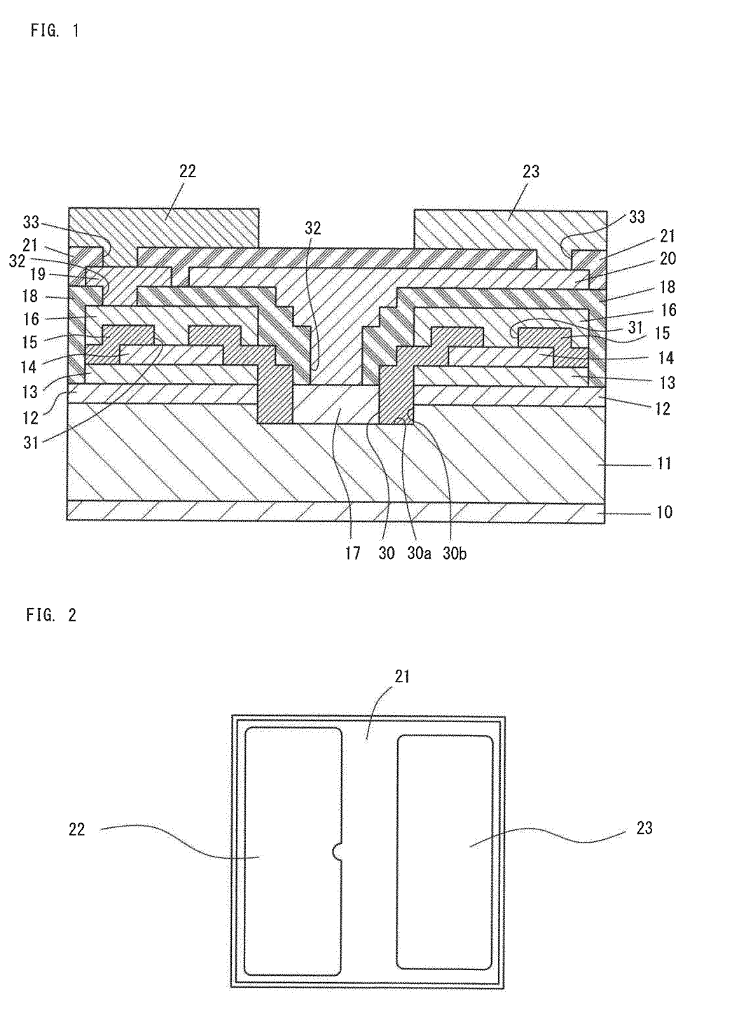

FIG. 1 is a schematic view of the structure of an ultraviolet light-emitting diode according to the first embodiment. FIG. 2 is a top view of the light-emitting diode according to the first embodiment. The light-emitting diode according to the first embodiment is of a flip-chip type. As shown in FIG. 1, the light-emitting diode includes a substrate 10, an n-type layer 11, a light-emitting layer 12, a p-type layer 13, a transparent electrode 14, a DBR layer 15, a first p-electrode 16, a first n-electrode 17, a first interlayer insulating film 18, a second p-electrode 19, a second n-electrode 20, a second interlayer insulating film 21, a third p-electrode 22, and a third n-electrode 23. The first p-electrode 16 and the first n-electrode 17 correspond to the first electrode of the present invention. The second p-electrode 19 and the second n-electrode 20 correspond to the second electrode of the present invention. Components of the light-emitting diode will be described in detail below.

### Structure of Substrate 10

The substrate 10 is made of sapphire and has a c-plane main surface. The substrate 10 is a square in a plan view. The substrate 10 has an uneven shape on the surface thereof. The uneven shape improves the light extraction efficiency, and the crystallinity is improved by suppressing the occurrence of cracks or hillocks in the semiconductor layers deposited on the uneven shape.

A buffer layer, a buried layer, and an undoped layer (all not illustrated) are sequentially deposited on the substrate 10. The buffer layer is made of AlN formed by sputtering and has a thickness of 15 nm to 30 nm. The buried layer is made of undoped AlGaN. The Al composition ratio is 10%. The buried layer is a layer for flattening the surface by leveling the unevenness through lateral growth. The undoped layer is made of undoped AlGaN having a thickness of 0.1 μm to 3 μm and has an Al composition ratio of 10% to 15%. By forming the undoped layer, dislocation is reduced and crystal quality is improved, and stress generated due to difference in lattice constant from the substrate 10 is relaxed.

### Structure of n-Type Layer 11

The n-type layer 11 is formed on the undoped layer. The n-type layer 11 is made of Si-doped n-AlGaN and has a thickness of 0.1 μm to 3 μm. The n-type layer 11 has any Al composition ratio as long as it is higher than the Al composition ratio of the undoped layer under the n-type layer, for example, 10% to 50%. The n-type impurity is Si, and the Si concentration is 1×10¹⁸/cm³ to 1×10²⁰/cm³.

### Structure of Light-Emitting Layer 12

The light-emitting layer 12 is formed on the n-type layer 11. The light-emitting layer 12 has a MQW structure in which a well layer and a barrier layer are repeatedly deposited. The number of repetitions is, for example, two to five. The material of the well layer is selected according to emission wavelength. In the case of far-ultraviolet light emission, AlGaN is used. In the case of near ultraviolet light emission (with a wavelength of 365 nm or more), GaN or InGaN is used. The Al composition ratio or In composition ratio of the well layer is designed according to the emission wavelength of the light-emitting diode. The barrier layer is made of AlGaN with an Al composition ratio higher than the Al composition of the well layer. The thickness of the well layer is one molecular layer, i.e., half lattice constant, to 15 nm, and the thickness of the barrier layer is 2 nm to 15 nm. The well layer or the barrier layer may be made of AlGaInN. The light-emitting layer 12 may have a SQW (single quantum well) structure.

### Structure of p-Type Layer 13

The p-type layer 13 is formed on the light-emitting layer 12. The p-type layer 13 comprises an electron blocking layer and a p-type contact layer sequentially deposited on the light-emitting layer 12.

The electron blocking layer is made of Mg-doped p-AlGaN. The Mg concentration is 1×10¹⁹/cm³ to 1×20²¹/cm³, the Al composition ratio is 30% to 50%, and the thickness is 1 nm to 50 nm. By forming the electron blocking layer, it is suppressed that electrons are diffused to the p-type contact layer side and the emission efficiency is reduced. To enhance this suppression effect, the Al composition ratio of the electron blocking layer is preferably higher by 10% or more than the Al composition ratio of the barrier layer of the light-emitting layer 12.

The p-type contact layer comprises a first layer made of Mg-doped p-AlGaN and a second layer made of Mg-doped p-GaN sequentially deposited on the electron blocking layer. The first layer has a thickness of 20 nm to 100 nm and an Mg concentration of 1×10¹⁹/cm³ to 1×20²⁰/cm³. The second layer has a thickness of 2 nm to 10 nm and an Mg concentration of 1×10²⁰/cm³ to 1×20²²/cm³. The Al composition ratio of the first layer is preferably lower than the Al composition ratio of the electron blocking layer and higher than the Al composition ratio of the n-type layer 11, for example, 10% to 20%.

In a part of the surface of the p-type layer 13, a plurality of holes 30 reaching the n-type layer 11 are formed in a dot pattern. These holes are for connecting the first n-electrode 17 with the n-type layer 11.

### Structure of Transparent Electrode 14

The transparent electrode 14 is formed on almost the entire surface of the p-type contact layer. The transparent electrode 14 is made of IZO (zinc-doped indium oxide). Any material such as ITO (tin-doped indium oxide) and ICO (cerium-doped indium oxide) other than IZO may be used as long as it is a conductive material transparent to the emission wavelength of the light-emitting diode.

### Structure of DBR Layer 15

The DBR layer 15 is continuously formed in a film so as to cover the transparent electrode 14 and the side 30b and bottom surfaces 30a of the holes 30. The DBR layer 15 is a multilayer film formed by alternately depositing SiO₂ and TiO₂. The number of layers is 31. The thicknesses of SiO₂ and TiO₂ are set so as to reflect light with an emission wavelength by interference. The DBR layer 15 efficiently reflects the light emitted from the light-emitting layer 12 to the side opposite to the light extraction side, to the light extraction side (substrate 10 side), thereby enhancing the light extraction efficiency.

The DBR layer 15 has a plurality of holes 31 and 30 passing through the DBR layer 15 in a predetermined region. Through the holes 31, the first p-electrode 16 and the transparent electrode 14 are connected, and through the holes 30, the first n-electrode 17 and the n-type layer 11 are connected.

### Structure of First p-Electrode 16

The first p-electrode 16 is formed in a region corresponding to the upper part of the transparent electrode 14 and the p-type layer 13 on the DBR layer 15. The first p-electrode 16 is formed so as to fill in the holes 31 provided in the DBR layer 15. Thus, the first p-electrode 16 is connected to the transparent electrode 14. That is, the first p-electrode 16 serves as a p-type contact electrode.

The first p-electrode 16 is formed of Ti/Ru/Au/Ta wherein the symbol “/” refers to a layered structure; for example, “A/B” refers to a layered structure in which layer B is formed after formation of layer A. The same shall apply hereinafter. The Ti layer is a layer for making adhesion and contact with the transparent electrode 14. The Ru layer is a layer for enhancing reflectance of ultraviolet light with an emission wavelength. The Au layer is a layer for securing conductivity. The Ta layer is a layer for improving corrosion resistance, reducing the difference in thermal expansion coefficient between the Ta layer and the first interlayer insulating film 18, and relaxing the internal stress of the first interlayer insulating film 18. Since the first p-electrode 16 is a multilayer whose top layer (the layer in contact with the first interlayer insulating film 18) is formed of Ta, crack occurrence in the first interlayer insulating film 18 and peeling of the first interlayer insulating film 18 from the first p-electrode 16 can be suppressed when the light-emitting diode according to the first embodiment is exposed to a high temperature.

In the first embodiment, the top layer of the first p-electrode 16 is a Ta layer. However, the top layer is not limited to this. As long as the difference in thermal expansion coefficient between the bottom layer of the first interlayer insulating film 18 (SiO₂ layer 18A in the first embodiment) and the top layer of the first p-electrode 16 is 0×10⁻⁶/K to 22×10⁻⁶/K, any other material such as Mo may be used.

### Structure of First n-Electrode 17

The first n-electrode 17 is formed on the surface of the n-type layer 11 exposed through the holes 30 formed in the DBR layer 15. The first n-electrode 17 is formed of the same material as that of the first p-electrode 16, i.e. Ti/Ru/Au/Ta. As in the first p-electrode 16, since the top layer of the first n-electrode 17 is formed of Ta, the same effect is obtained. That is, when the light-emitting diode according to the first embodiment is exposed to a high temperature, the internal stress of the first interlayer insulating film 18 can be reduced, and crack occurrence in the first interlayer insulating film 18 and peeling from the first n-electrode 17 can be suppressed.

### Structure of First Interlayer Insulating Film 18

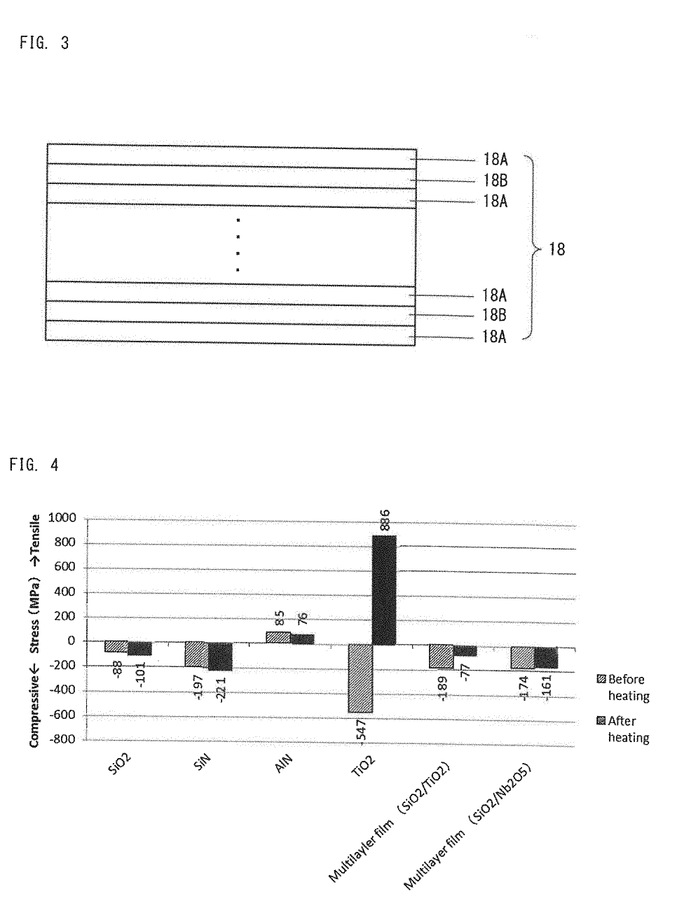

The first interlayer insulating film 18 is continuously formed in a film on the DBR layer 15, the first p-electrode 16, and the first n-electrode 17. The first interlayer insulating film 18 is a multilayer film formed by alternately depositing a SiO₂ layer 18A and a TiO₂ layer 18B as shown in FIG. 3. The number of layers is 11. The bottom layer (layer in contact with the first p-electrode 16 and the first n-electrode 17) and the top layer (the layer in contact with the second p-electrode 19 and the second n-electrode 20) are the SiO₂ layer 18A.

Since the first interlayer insulating film 18 is a multilayer film, when the light-emitting diode according to the first embodiment is exposed to a high temperature, peeling of the first interlayer insulating film 18 from the first p-electrode 16 and the first n-electrode 17 is suppressed, and crack occurrence in the first interlayer insulating film 18 is suppressed. The reason is as follows. The SiO₂ layer 18A is formed of a material having a property of generating compressive stress, and the property does not change when heated. On the contrary, the TiO₂ layer 18B is formed of a material whose property changes from generating compressive stress to generating tensile stress when heated. Here, compressive stress and tensile stress are defined as stress in an in-plane direction, that is, a horizontal direction of the layer. Moreover, property change is defined as polarity change of strain. Therefore, when the light-emitting diode according to the first embodiment is exposed to a high temperature (e.g., 400° C. or higher), the TiO₂ layer 18B of the first interlayer insulating film 18 changes its property to generate tensile stress. The tensile stress generated by the TiO₂ layer 18B and the compressive stress generated by the SiO₂ layer 18A counteract each other. As a result, the internal stress of the first interlayer insulating film 18 is relaxed, and crack occurrence in the first interlayer insulating film 18 and peeling of the first interlayer insulating film 18 from the first p-electrode 16 and the first n-electrode 17 are suppressed.

Since the first interlayer insulating film 18 is a multilayer film, the breakdown voltage of the light-emitting diode is increased. The reason is as follows. Since the first interlayer insulating film 18 is a multilayer film formed by alternately depositing different materials, defects such as cracks occurred in one layer of the first interlayer insulating film 18 are not taken over to the upper layer. Therefore, defects are suppressed from continuing in the thickness direction. As a result, the breakdown voltage of the first interlayer insulating film 18 is increased.

In the first embodiment, the number of layers in the first interlayer insulating film 18 is 11. However, any number of layers is acceptable as long as it is three or more. When the number of layers is two, peeling may occur at the interface. The number of layers is more preferably three to eleven.

In the first embodiment, the bottom layer and the top layer in the first interlayer insulating film 18 are a SiO₂ layer 18A. However, one or both of them may be a TiO₂ layer 18B. Actually, the bottom layer and the top layer are preferably a SiO₂ layer 18A as in the first embodiment in terms of adhesion with the electrode.

The ratio of thickness of the TiO₂ layer 18B to the sum of thicknesses of the SiO₂ layer 18A and the TiO₂ layer 18B (hereinafter, referred to thickness ratio) is preferably 0.1 to 0.5. That is, the thickness ratio is defined as thickness of the TiO₂ layer/(thickness of the TiO₂ layer+thickness of the SiO₂ layer). Within this range, the internal stress applied to the first interlayer insulating film 18 can be further reduced, and the breakdown voltage can be further increased. The thickness ratio is more preferably 0.1 to 0.4, and further preferably 0.2 to 0.3.

In the first interlayer insulating film 18, the SiO₂ layers 18A need not have the same thickness. The same is applied to the TiO₂ layer 18B. In that case, the ratio of the sum of thicknesses of the TiO₂ layers 18B to the sum of thicknesses of the SiO₂ layers 18A and the sum of thicknesses of the TiO₂ layers 18B is preferably within the above range.

The first interlayer insulating film 18 may have a DBR structure having a high reflectance to the emission wavelength by setting the thicknesses of the SiO₂ layer 18A and the TiO₂ layer 18B to predetermined values. The light, which is not reflected by the DBR layer 15, can be reflected by the first interlayer insulating film 18, thereby further improving the light extraction efficiency.

In the first embodiment, the first interlayer insulating film 18 is a multilayer film formed by alternately depositing TiO₂ and SiO₂. However, any other material may be used instead of SiO₂ as long as it has a property of generating compressive stress and the property does not change when heated. For example, SiN and Al₂O₃ may be used. Any material may be used instead of TiO₂ as long as it has a property of generating tensile stress after heating (particularly 400° C. or higher).

### Structures of Second p-Electrode 19 and Second n-Electrode 20

The second p-electrode 19 and the second n-electrode 20 are formed apart from each other on the first interlayer insulating film 18. The second p-electrode 19 and the second n-electrode 20 are formed of the same material as that of the first p-electrode 16. The first p-electrode 16 and the second p-electrode 19 are connected through the holes 32 formed in the first interlayer insulating film 18. In the same way, the first n-electrode 17 and the second n-electrode 20 are connected through the holes 32 formed in the first interlayer insulating film 18.

### Structure of Second Interlayer Insulating Film 21

The second interlayer insulating film 21 is continuously formed in a film on the second p-electrode 19, the second n-electrode 20, and the first interlayer insulating film 18. The second interlayer insulating film 21 is formed of SiO₂. Holes 33 passing through the second interlayer insulating film 21 are formed in a predetermined region of the second interlayer insulating film 21. Through the holes 33, the second p-electrode 19 and the third p-electrode 22 are connected, and the second n-electrode 20 and the third n-electrode 23 are connected.

The second interlayer insulating film 21 may be a multilayer film same as the first interlayer insulating film 18. Cracks or peeling of the second interlayer insulating film 21 can be suppressed, thereby further suppressing deterioration of the electrical and optical properties of the light-emitting diode.

### Structures of Third p-Electrode 22 and Third n-Electrode 23

The third p-electrode 22 and the third n-electrode 23 are formed apart from each other on the second interlayer insulating film 21. As shown in FIG. 2, the third p-electrode 22 and the third n-electrode 23 are almost rectangles. The third p-electrode 22 and the third n-electrode 23 are connected, through the holes 33 formed in the second interlayer insulating film 21, to the second p-electrode 19 and the second n-electrode 20, respectively. When the light-emitting diode according to the first embodiment is flip-chip mounted in a face down, the third p-electrode 22 and the third n-electrode 23 are connected to the electrode pattern, i.e., land pattern, which is formed on a mounting substrate outside the diode.

In the light-emitting diode according to the first embodiment, the p-electrode has a three-layered structure including the first p-electrode 16, the second p-electrode 19, and the third p-electrode 22, where the first interlayer insulating film 18 and the second interlayer insulating film 21 are interposed among the electrodes 16, 19, and 22. Similarly, the n-electrode has a three-layered structure including the first n-electrode 17, the second n-electrode 20, and the third n-electrode 23, where the first interlayer insulating film 18 and the second interlayer insulating film 21 are interposed among the electrodes 17, 20, and 23. This achieves the structure where the electrode is in contact with the n-type layer 11 and the p-type layer 13 in a plurality of dots so as to uniformly diffuse current over the surface. In ultraviolet light emission, the Al composition ratio of the semiconductor layer is high, and it is difficult to diffuse current over the surface. Therefore, such an electrode structure is suitable.

In the light-emitting diode according to the first embodiment, the first interlayer insulating film 18 is a multilayer film formed by alternately depositing TiO₂ generating tensile stress and SiO₂ generating compressive stress. Therefore, when the light-emitting diode is exposed to a high temperature, the stress applied to the first interlayer insulating film 18 is reduced, thereby suppressing cracks in the first interlayer insulating film 18 and peeling of the first interlayer insulating film 18 from the first p-electrode 16 or the first n-electrode 17. As a result, deterioration of electrical and optical properties or partial light emission of the light-emitting diode is suppressed. Moreover, corrosion resistance is improved because the first interlayer insulating film 18 is a multilayer film.

Next will be described the experimental results regarding the first embodiment.

FIG. 4 is a graph comparing the internal stresses generated in the first interlayer insulating films 18 made of different materials. Comparison was made on how the internal stress varies by heating. Heating was performed at 550° C. for 40 seconds in a nitrogen atmosphere.

As shown in FIG. 4, when the first interlayer insulating film 18 is a single SiO₂ layer having a thickness of 900 nm or a single SiN layer having a thickness of 900 nm, compressive stress was generated in the first interlayer insulating film 18, and the property did not change before and after heating. When the first interlayer insulating film 18 is a single AlN layer having a thickness of 900 nm, tensile stress was generated in the first interlayer insulating film 18, and the property did not change before and after heating. On the other hand, when the first interlayer insulating film 18 is a single TiO₂ layer having a thickness of 800 nm, compressive stress was generated before heating, and the stress is larger than the stress in the single SiO₂ layer or the single SiN layer. Tensile stress was generated after heating, and the stress is larger than the stress in the single AIN layer. It was found that the property of TiO₂ varies by heating.

When the first interlayer insulating film 18 is a multilayer film formed by alternately depositing TiO₂ having a thickness of 334 nm and SiO₂ having a thickness of 1105 nm (up to eleven layers), compressive stress was generated both before and after heating. However, after heating, the compressive stress was more reduced than that in the single SiO₂ layer.

When the first interlayer insulating film 18 is a multilayer film formed by alternately depositing Nb₂O₅ having a thickness of 400 nm and SiO₂ having a thickness of 1360 nm (up to eleven layers), compressive stress was generated both before and after heating, and the compressive stress was larger than that in the single SiO₂ layer.

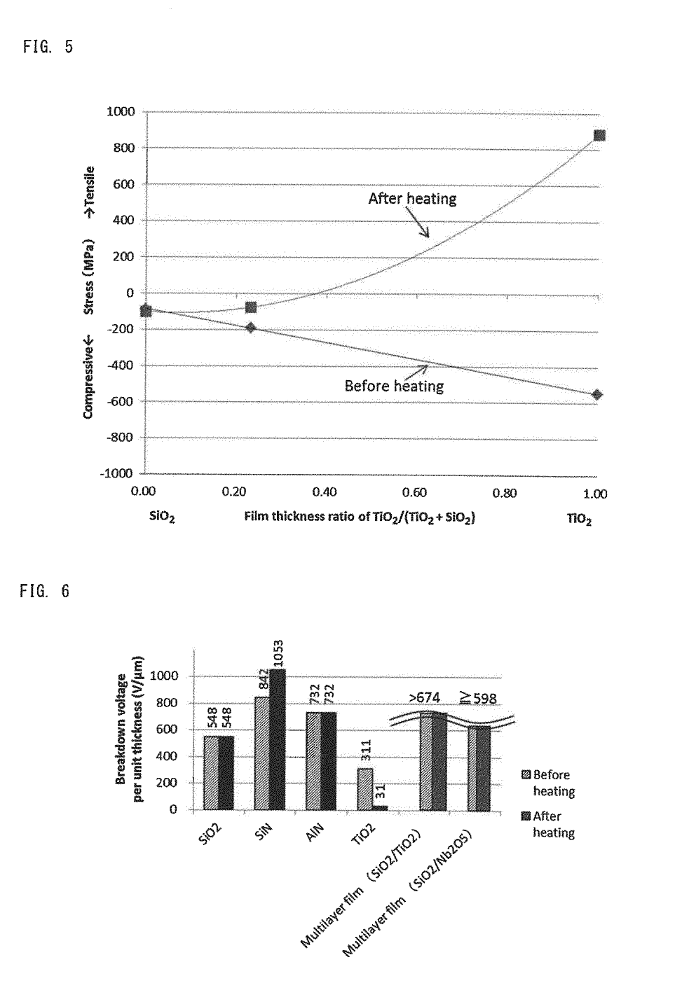

FIG. 5 is a graph showing the relationship between film thickness ratio and internal stress when the first interlayer insulating film 18 is a multilayer film of SiO₂ and TiO₂. The internal stresses both before and after heating are shown. The heating conditions are the same as in FIG. 4. The film thickness ratio is the ratio of thickness of the TiO₂ layer to the sum of thicknesses of the SiO₂ layer and the TiO₂ layer.

As shown in FIG. 5, before heating, the compressive stress monotonously increased as the film thickness ratio increases. After heating, the compressive stress was gradually reduced as the film thickness ratio increases, and the stress was 0 when the film thickness ratio is near 0.38. After that, the compressive stress was changed to the tensile stress, and the tensile stress gradually increased.

It was found from the results of FIGS. 4 and 5 that the internal stress of the first interlayer insulating film 18 before and after heating can be adjusted by adjusting the film thickness ratio when the first interlayer insulating film 18 is a multilayer of TiO₂ and SiO₂, thereby reducing the internal stress applied to the first interlayer insulating film 18. Particularly, the film thickness ratio needs to be within a range of 0.1 to 0.5 to suppress the internal stress of the first interlayer insulating film 18 after heating than in the single SiO₂ layer.

FIG. 6 is a graph comparing the breakdown voltage of the first interlayer insulating film 18 when the first interlayer insulating film 18 is made of different materials same as in FIG. 4. Comparison was also made on how the breakdown voltage varies by heating. The heating conditions are the same as in FIG. 4. The breakdown voltage is a value converted per unit thickness (1 μm).

As shown in FIG. 6, when the first interlayer insulating film 18 is a single SiN layer or a single AlN layer, the breakdown voltage was higher than in the single SiO₂ layer both before and after heating. On the other hand, when the first interlayer insulating film 18 is a single TiO₂ layer, the breakdown voltage was lower than in the single SiO₂ layer both before and after heating, and remarkably lower particularly after heating.

When the first interlayer insulating film 18 is a multilayer film formed by alternately depositing TiO₂ having a thickness of 334 nm and SiO₂ having a thickness of 1105 nm (up to eleven layers), the breakdown voltage was higher both before and after heating than in the single SiO₂ layer, and exceeded the measurement limit.

When the first interlayer insulating film 18 is a multilayer film formed by alternately depositing Nb₂O₅ having a thickness of 400 nm and SiO₂ having a thickness of 1360 nm (up to eleven layers), the breakdown voltage was higher both before and after heating than in the single SiO₂ layer, and exceeded the measurement limit.

Thus, it was found that when the first interlayer insulating film 18 is a multilayer film, a high breakdown voltage exceeding the measurement limit is obtained.

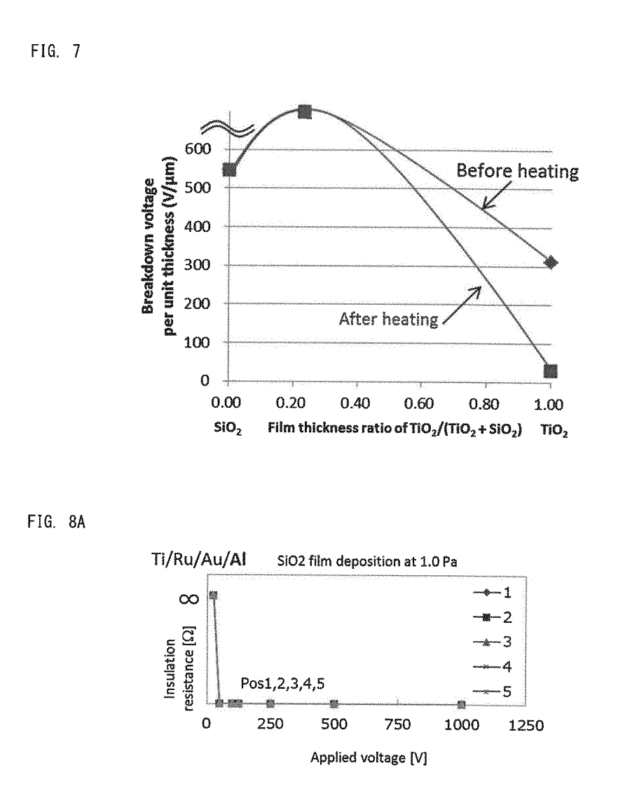

FIG. 7 is a graph showing the relationship between film thickness ratio and breakdown voltage when the first interlayer insulating film 18 is a multilayer of SiO₂ and TiO₂. The breakdown voltage, both before and after heating, is shown. FIG. 7 is a graph showing the relationship between film thickness ratio and breakdown voltage before and after heating. The heating conditions are the same as in FIG. 4. The definition of the film thickness ratio is the same as in FIG. 5. The breakdown voltage is a value converted per unit thickness (1 μm) in the same way as in FIG. 6.

As shown in FIG. 7, both before and after heating, the breakdown voltage increases as the thickness ratio increases up to the film thickness ratio of near 0.23, and the film thickness ratio decreases after the film thickness ratio exceeds 0.23. The film thickness ratio needs to be 0.55 or less to obtain the breakdown voltage larger than that of the single SiO₂ layer after heating.

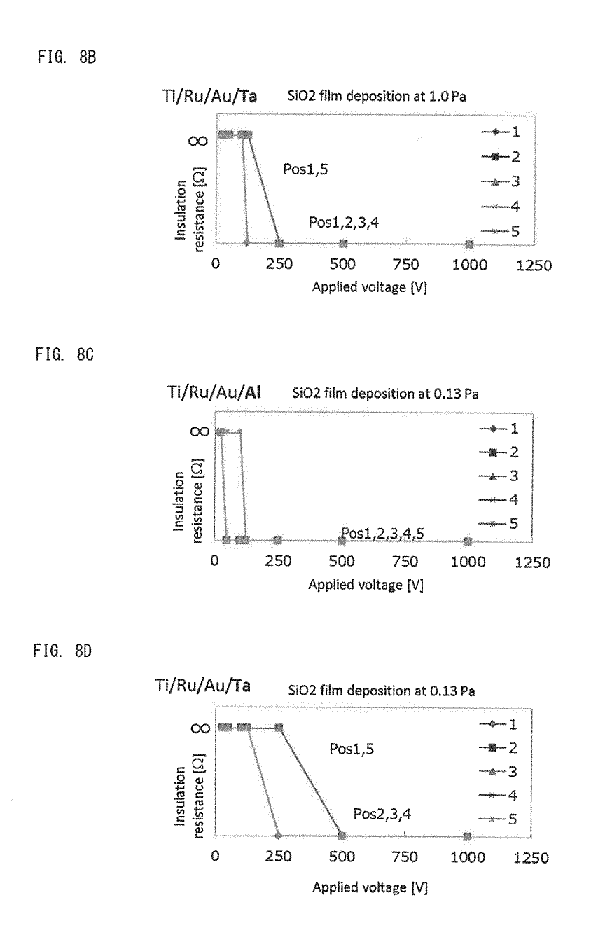

FIGS. 8A to 8D are graphs showing the insulation resistances of the insulating film after heating when the electrode was formed on the insulating film. Samples were prepared by sequentially depositing an electrode and a SiO₂ insulating film on a Si substrate. The electrode was formed of two types of materials: Ti/Ru/Au/Al and Ti/Ru/Au/Ta. FIG. 8A shows the case where the electrode was formed of Ti/Ru/Au/Al, and FIG. 8B shows the case where the electrode was formed of Ti/Ru/Au/Ta, at an insulating film deposition pressure of 1.0 Pa. FIG. 8C shows the case where the electrode was formed of Ti/Ru/Au/Al, and FIG. 8D shows the case where the electrode was formed of Ti/Ru/Au/Ta, at an insulating film deposition pressure of 0.13 Pa. The heating conditions were the same as in FIG. 4. The numbers 1 to 5 in FIG. 8 represent the measurement positions of wafer.

As shown in FIGS. 8A to 8D, when the film deposition pressure is either 1.0 Pa or 0.13 Pa, the breakdown voltage was increased by changing the materials of the top layer of the electrode from Al to Ta.

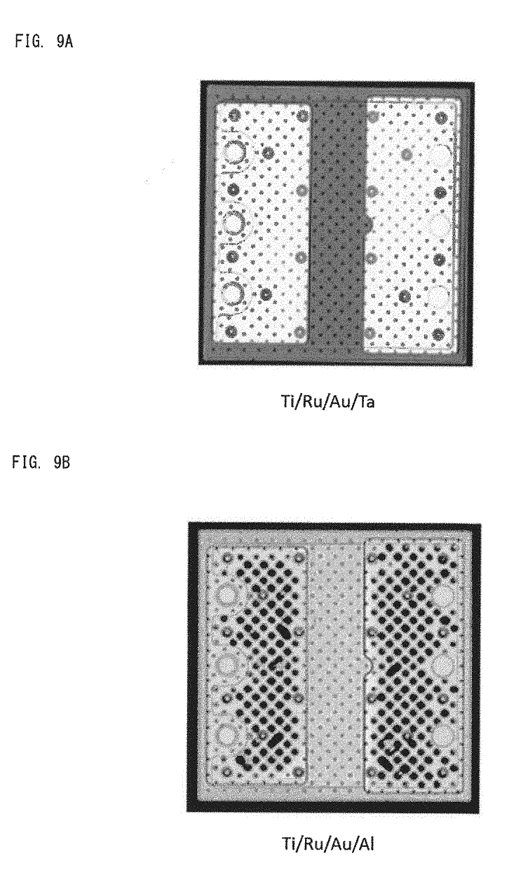

FIGS. 9A and 9B are photos of the top side of the light-emitting diode after heating. FIG. 9A shows the light-emitting diode of Example 1 in which the first p-electrode 16 and the first n-electrode 17 were formed of Ti/Ru/Au/Ta, and FIG. 9B shows the light-emitting diode of Comparative Example in which the first p-electrode 16 and the first n-electrode 17 were formed of Ti/Ru/Au/Al.

As shown in FIGS. 9A and 9B, a plurality of black dot regions was observed in the light-emitting diode of Comparative Example. These regions correspond to the regions where the first interlayer insulating film 18 was peeled from the first p-electrode 16 or the first n-electrode 17. On the other hand, black dot regions were not observed in the light-emitting diode of Example 1, and there was no peeling of the first interlayer insulating film 18.

As shown in FIGS. 8A to 8D and FIGS. 9A and 9B, by changing the top layer of the first p-electrode 16 and the first n-electrode 17 from Al to Ta, insulation resistance and breakdown voltage of the first interlayer insulating film 18 were increased, thereby suppressing peeling. The following reason is considered. Since difference in the linear expansion coefficient between SiO₂ and Al is so large as 22.4×10⁻⁶/K, cracks or peelings occur in SiO₂ during heating due to difference in the linear expansion coefficient. On the contrary, since difference in the linear expansion coefficient between SiO₂ and Ta is so small as 5.7×10⁻⁶/K, cracks or peeling in SiO₂ is suppressed.

### Second Embodiment

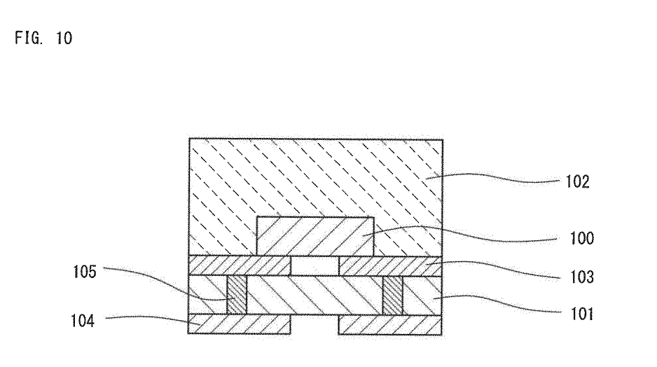

The second embodiment is a light-emitting device having the light-emitting diode according to the first embodiment sealed with glass. As shown in FIG. 10, the light-emitting device according to the second embodiment comprises a light-emitting diode 100 according to the first embodiment, a mounting substrate 101 for mounting the light-emitting diode 100, and a sealing glass 102 for sealing the light-emitting diode 100.

The mounting substrate 101 is a square ceramic substrate made of AlN in a plan view. A wiring pattern 103 is formed on the surface of the mounting substrate 101 (the surface on which the light-emitting diode 100 is mounted).

A back electrode pattern 104 is formed on the rear surface of the mounting substrate 101. The wiring pattern 103 and the back electrode pattern 104 are connected through a via 105. The via 105 is formed by filling the columnar hole passing through the mounting substrate 101 with a conductive material. The light-emitting diode 100 is flip-chip mounted on the mounting substrate 101, and the electrode of the light-emitting diode 100 and the wiring pattern 103 of the mounting substrate 101 are connected through a bump (not illustrated).

The mounting substrate 101 may be formed of a ceramic other than AlN. For example, Al₂O₃ may be used. In addition, metal, glass, and glass ceramic may be used.

The sealing glass 102 is a rectangular parallelepiped glass formed on the mounting substrate 101 so as to cover the light-emitting diode 100. The side surfaces of the sealing glass 102 coincide with the side surfaces of the mounting substrate 101, and the light-emitting device is a rectangular parallelepiped as a whole.

The sealing glass 102 is a solidified material of a paste in which quartz glass powder is dispersed using phosphate glass as a solvent. The phosphate glass may be SnO—P₂O₅ based glass, ZnO—P₂O₅ based glass, ZnO—SnO—P₂O₅ based glass, P₂O₅—F based glass, and others. Other than phosphate glass, any low melting point glass having a softening point of 500° C. or less may be used.

The sealing glass 102 is mixed with phosphor. This converts ultraviolet light emitted from the light-emitting diode 100 to white light. Needless to say, ultraviolet light may be emitted as it is without being mixed with phosphor.

Next will be described the method for producing a light-emitting device according to the second embodiment.

Firstly, a light-emitting diode 100 is flip-chip mounted on a mounting substrate 101. Any conventionally known mounting method may be used. For example, bumps are formed on a third p-electrode 22 and a third n-electrode 23 of the light-emitting diode 100, the third p-electrode 22 and the third n-electrode 23 of the light-emitting diode 100 is directed toward the mounting substrate 101 side, the positions of the bumps of the light-emitting diode 100 are aligned with predetermined positions of the wiring pattern 103 on the mounting substrate 101, and the bumps are melted with vibration by ultrasonic waves. Thus, the third p-electrode 22 and the third n-electrode 23 of the light-emitting diode 100 are connected to the wiring pattern 103 on the mounting substrate 101.

Subsequently, the sealing glass 102 is disposed on the top of the mounting substrate 101. After heating up to the sealing temperature, the sealing glass 102 and the mounting substrate 101 are pressurized to be stuck each other, and then are cooled down to a room temperature. Thus, the light-emitting diode 100 is sealed with the sealing glass 102. The sealing temperature may be any temperature in the range from the softening point to the melting point of the sealing glass 102, for example, 400° C. or higher.

The light-emitting diode 100 is exposed to a high temperature by glass sealing. However, since the first interlayer insulating film 18 is a multilayer film formed by alternately depositing a SiO₂ layer 18A and a TiO₂ layer 18B, crack occurrence in the first interlayer insulating film 18 or peeling of the first interlayer insulating film 18 from the first p-electrode 16 or the first n-electrode 17 are suppressed.

The light-emitting device according to the second embodiment uses the light-emitting diode 100 according to the first embodiment. Therefore, even when the light-emitting diode 100 is exposed to a high temperature when sealing with glass, peeling of the first interlayer insulating film 18 from the first p-electrode 16 or the first n-electrode 17 or crack occurrence in the first interlayer insulating film 18 are suppressed in the light-emitting diode 100. Thus, the electrical and optical properties of the light-emitting diode 100 are suppressed from being deteriorated, and partial light emission is suppressed.

### Variations

The light-emitting diode according to the first embodiment emits ultraviolet light. However, the present invention is not limited to ultraviolet light emission. The light-emitting diode according to the first embodiment may emit light having any emission wavelength.

The present invention is not limited to a light-emitting diode, and may also be applied to any semiconductor device. The present invention may be applied to, for example, a power device or a high frequency device such as MOSFET, IGBT, and HFET.

The present invention is applicable to various semiconductor device, particularly effective to an ultraviolet light-emitting diode.

What is claimed is:

1. A semiconductor device comprising:
a sapphire substrate;
a Group III nitride semiconductor layer formed on the sapphire substrate;
a first electrode formed on or above the Group III nitride semiconductor layer;
an interlayer insulating film formed on the first electrode; and
a second electrode formed on the interlayer insulating film, the second electrode being connected with the first electrode through holes formed in the interlayer insulating film,
wherein the interlayer insulating film is a multilayer film formed by alternately depositing a first insulating film made of a material generating a tensile stress and a second insulating film made of a material generating a compressive stress in three or more layers.

2. The semiconductor device according to claim 1, wherein a ratio of thickness of the first insulating film to a sum of thicknesses of the first insulating film and the second insulating film is 0.1 to 0.5.

3. The semiconductor device according to claim 1, wherein a top layer and a bottom layer of the interlayer insulating film are the second insulating film.

4. The semiconductor device according to claim 2, wherein a top layer and a bottom layer of the interlayer insulating film are the second insulating film.

5. The semiconductor device according to claim 1, wherein the second insulating film is formed of SiO₂.

6. The semiconductor device according to claim 2, wherein the second insulating film is formed of SiO₂.

7. The semiconductor device according to claim 3, wherein the second insulating film is formed of SiO₂.

8. The semiconductor device according to claim 5, wherein the first electrode is a multilayer, and a top layer of the first electrode is formed of at least one of Ta and Mo.

9. The semiconductor device according to claim 6, wherein the first electrode is a multilayer, and a top layer of the first electrode is formed of at least one of Ta and Mo.

10. The semiconductor device according to claim 1, wherein the first insulating film is formed of TiO₂.

11. The semiconductor device according to claim 2, wherein the first insulating film is formed of TiO₂.

12. The semiconductor device according to claim 5, wherein the first insulating film is formed of TiO₂.

13. The semiconductor device according to claim 6, wherein the first insulating film is formed of TiO₂.

14. The semiconductor device according to claim 1, wherein the device is a light-emitting diode.

15. The semiconductor device according to claim 14, wherein the device emits ultraviolet light.

16. The semiconductor device according to claim 14, wherein the interlayer insulating film has a DBR structure.

17. A light-emitting device having the semiconductor device according to claim 14 and a sealing glass for sealing the semiconductor device.
